(19) United States
(12) Patent Application Publication
(10) Pub. No.: US 2006/0049036 A1
(43) Pub. Date: Mar. 9, 2006

(54) Method and apparatus for real-time control and monitor of deposition processes

(75) Inventors: Cheng-Hung Chang, Hsinchu (TW); Jhi-Cherng Lu, Taipei City (TW); Joung-Wei Liou, Hsinchu County (TW); Chu-Yun Fu, Taipei (TW); Weng Chang, Hsin-Chu (TW); Syung-Ming Jang, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/936,905

(22) Filed: Sep. 9, 2004

(51) Int. Cl. C23C 14/00

(52) U.S. Cl. 204/192.33; 204/192.12

(57) ABSTRACT

A method comprises measuring an RF voltage and ion current at a wafer during a plasma-enhanced deposition process, determining a sputter rate in response to the RF voltage and ion current measurements, detecting an abnormal condition in response to one of the RF voltage and ion current measurements, and sputter rate, and taking a corrective action in response to detecting an abnormal condition.

### BACKGROUND

Deposition processes are widely used in semiconductor fabrication to form various device features such as shallow trench isolation (STI), inter-layer dielectrics (ILD), and inter-metal dielectrics (IMD). In particular, high density plasma (HDP) enhanced chemical vapor deposition (CVD) uses a reactive chemical gas along with physical ion generation by using a radio frequency (RF) generated plasma to enhance film deposition. Because deposition is a function of sputtering, it is desirable to monitor the sputter rate in order to determine whether the deposition process is progressing normally.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic diagram of an embodiment of apparatus for controlling and monitoring deposition processes;

FIG. 2 is a schematic diagram of a circuit model of the plasma sheath near an RF-biased electrode in the plasma chamber; and

FIG. 3 is a simplified flowchart of an embodiment of a process of monitoring the deposition process.

### DETAILED DESCRIPTION

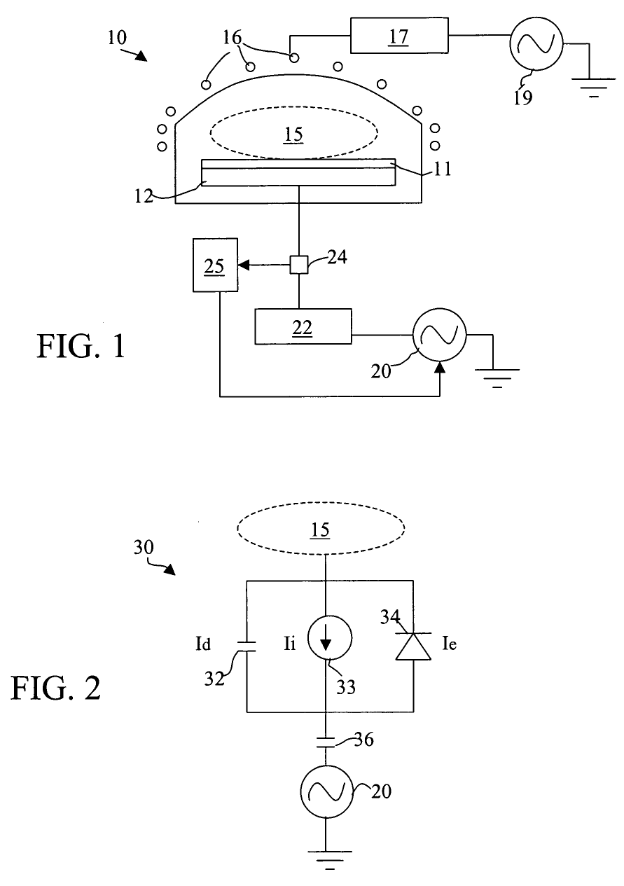

FIG. 1 is a schematic diagram of an embodiment of apparatus 10 for controlling and monitoring deposition processes. A wafer 11 is mounted on an electrostatic chuck 12 and placed inside a deposition chamber 13. Deposition chamber 13 may include a dielectric dome 14. Ion plasma 15 is generated in the chamber 13 by radio frequency (RF) fields supplied by top and side RF coils 16. Each coil 16 has its own RF power supply 19 as well as an RF matching network 17. The RF power supply 19 may comprise a controller operable to modulate the power output of the RF power supply 19. The RF matching network 17 is used to deliver the right amount of power to the coils 16 for plasma generation. The chuck is also RF-biased by an RF power supply 21 and an RF matching network 22. The RF power supply 20 may comprise a controller operable to modulate the power output of the RF power supply 20. A voltage/current (V/I) probe 24 is coupled between the chuck 12 and the RF matching network 22. An out put of the V/I probe 24 is further coupled to a microprocessor 25 or another suitable controller.

The V/I probe 24 is operable to measure, in-situ, the ion current and RF voltage on the wafer 11 during deposition. Using a plasma sheath model described in Edelberg et al., Modeling of the Sheath and the Energy Distribution of Ions Bombarding RF-Biased Substrates in High Density Plasma Reactors and Comparison to Experimental Measurements, Vol. 86, No. 9, Journal of Applied Physics, Nov. 1, 1999, the measured data may be used to estimate the ion current on the wafer 11. Edleberg et al. describes a circuit-equivalent 30 of this plasma sheath model, which is shown in FIG. 2. The plasma 15 is separated from the wafer 11 by a plasma sheath or envelope represented schematically as a capacitor 32, a current source 33, and a diode 34 coupled in parallel. The current though the diode 34, Iₑ, represents the variation of the electron current as a function of the sheath potential drop. The current source 33, Iᵢ, represents the current due to ions that enter the sheath from the plasma-sheath boundary at the Bohm velocity. The current across the capacitor 32, I_{d}, is the capacitive displacement current across the sheath. A capacitor 36 coupled between the devices representing the sheath and the RF power supply 20 represents the capacitance encountered between the wafer 11 and chuck 12 and the power supply 20.

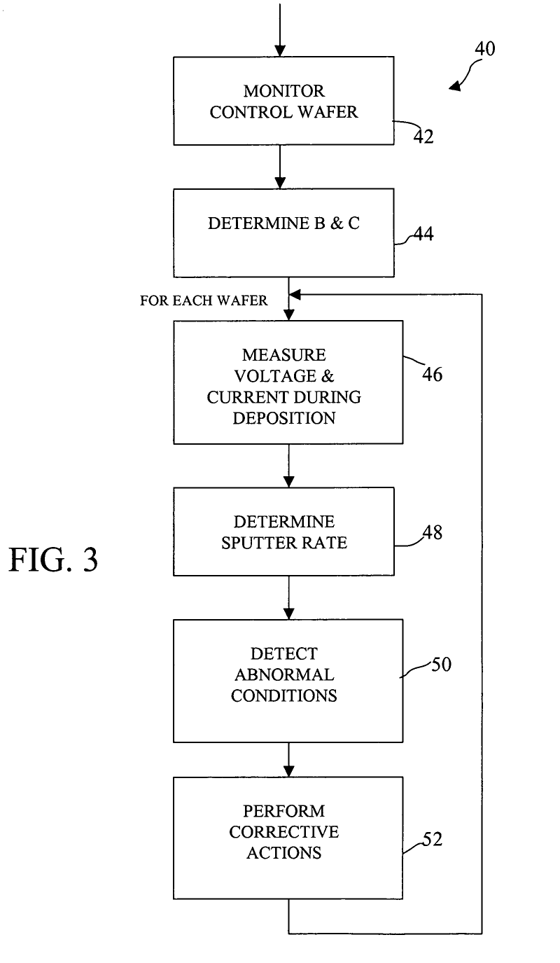

FIG. 3 is a simplified flowchart of an embodiment of a process 40 of performing real-time monitoring and controlling of the deposition process. In block 42, a deposition process using a control wafer is monitored and RF voltage and ion current measurements are obtained by the V/I probe 24 during the deposition process. Using these voltage and current measurements, and a sputter rate obtained after the deposition process by measuring the deposited film characteristics such as its thickness, constants B and C in the following equation may be calculated:
Sputter Rate=B*I_{ION}*(V_{RF}−C), (1)
where I_{ION} is the ion current measurement, and V_{RF} is the RF voltage measurement. Therefore, constants B and C for the particular equipment, equipment setup, deposition parameters, and other properties are computed in block 44. A modification of these properties may require that steps 42 and 44 be repeated for the new conditions. The ion current and RF voltage may be measured during the control wafer run to establish a range of expected values for these measurements.

Thereafter during each wafer production run, the RF voltage and ion current measurements are obtained in real-time during deposition, as shown in block 46. In block 48, these measurements may be provided to an algorithm executing in microprocessor 25 to compute the sputter rate using Equation (1). The current and voltage measurements may be obtained one or more times during each deposition of a device feature on the wafer. Alternatively, the current and voltage measurements and the computation of the sputter rate may be performed for selected runs, such as every other wafer, every five wafers, etc. or even randomly performed. Equation (1) may also be expressed as:
Sputter Rate=F*I_{ION}*(Sqrt(V_{RF})−Sqrt(G)), (2)
where F and G are constants that may be similarly obtained using the steps described above for obtaining B and C.

An abnormal condition during the deposition process may be detected by one or more of the measured ion current, RF voltage, and computed sputter rate deviating from the expected values in block 50. Upon detecting an abnormal condition as exemplified by the ion current, RF voltage or sputter rate, corrective action(s) may be performed in block 52. Such corrective action(s) may include reducing or increasing the power output of the power supplies 19 or 20, or halting the deposition runs, for example. The determination of what corrective action to perform upon detecting the abnormal conditions may be made by a human operator or a computer algorithm.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

What is claimed is:

1. A method comprising:
measuring an RF voltage and ion current at a wafer during a plasma-enhanced deposition process;
determining a sputter rate in response to the RF voltage and ion current measurements;
detecting an abnormal condition in response to one of the RF voltage and ion current measurements, and sputter rate;
taking a corrective action in response to detecting an abnormal condition.

2. The method of claim 1, wherein measuring an RF voltage and ion current comprises using a V/I probe coupled to a chuck supporting the wafer in a deposition chamber.

3. The method of claim 1, further comprising:
measuring an RF voltage and ion current at a control wafer during a plasma-enhanced deposition process forming a material layer;
determining a sputter rate in response a measured characteristic of the material layer formed on the control wafer; and
computing values for constants B and C according to the equation:
Sputter Rate=B*I_{ION}*(V_{RF}−C),
where I_{ION} is ion current and V_{RF} is RF voltage.

4. The method of claim 3, wherein determining a sputter rate comprises computing the sputter rate according to: Sputter Rate=B*I_{ION}*(V_{RF}−C).

5. The method of claim 1, wherein taking a corrective action comprises modifying power output of an RF power used to generate the plasma.

6. The method of claim 1, wherein detecting an abnormal condition comprises:
determining expected values for the ion current, RF voltage and sputter rate during the deposition process; and
detecting a deviation from the expected values.

7. The method of claim 1, further comprising:
measuring an RF voltage and ion current at a control wafer during a plasma-enhanced deposition process forming a material layer;
determining a sputter rate in response a measured characteristic of the material layer formed on the control wafer; and
computing values for constants B and C according to the equation:
Sputter Rate=F*I_{ION}*(Sqrt(V_{RF})−Sqrt(G)),
where I_{ION} is ion current and V_{RF} is RF voltage.

8. The method of claim 7, wherein determining a sputter rate comprises computing the sputter rate according to: Sputter Rate=F*I_{ION}*(Sqrt(V_{RF})−Sqrt(G)).

9. A system comprising:
means for measuring an RF voltage and ion current at a wafer during a plasma-enhanced deposition process;
means for determining a sputter rate in response to the RF voltage and ion current measurements;
means for detecting an abnormal condition in response to one of the RF voltage and ion current measurements, and sputter rate;
means for taking a corrective action in response to detecting an abnormal condition.

10. The system of claim 9, wherein means for measuring an RF voltage and ion current comprises a V/I probe coupled to a chuck supporting the wafer in a deposition chamber.

11. The system of claim 9, further comprising:
means for measuring an RF voltage and ion current at a control wafer during a plasma-enhanced deposition process forming a material layer;
means for determining a sputter rate in response a measured characteristic of the material layer formed on the control wafer; and
means for computing values for constants B and C according to the equation:
Sputter Rate=B*I_{ION}*(V_{RF}−C),
where I_{ION} is ion current and VRF is RF voltage.

12. The system of claim 11, wherein means for determining a sputter rate comprises means for computing the sputter rate according to: Sputter Rate=B*I_{ION}*(V_{RF}−C).

13. The system of claim 9, wherein means for taking a corrective action comprises means for modifying power output of an RF power used to generate the plasma.

14. The system of claim 9, wherein means for detecting an abnormal condition comprises:
means for determining expected values for the ion current, RF voltage and sputter rate during the deposition process; and
means for detecting a deviation from the expected values.

15. The system of claim 9, further comprising:
means for measuring an RF voltage and ion current at a control wafer during a plasma-enhanced deposition process forming a material layer;
means for determining a sputter rate in response a measured characteristic of the material layer formed on the control wafer; and
means for computing values for constants B and C according to the equation:
Sputter Rate=F*I_{ION}*(Sqrt(V_{RF})−Sqrt(G)),
where I_{ION} is ion current and V_{RF} is RF voltage.

16. The method of claim 15, wherein means for determining a sputter rate comprises means for computing the sputter rate according to: Sputter Rate=F*I_{ION}*(Sqrt(VRF)−Sqrt(G)).

17. A system comprising:
a plurality of RF-powered coils operable to generate an ion plasma in a deposition chamber;
a V/I probe coupled to a chuck in the deposition chamber holding a wafer, the V/I probe operable to measure an ion current and a RF voltage at the wafer during a plasma-enhanced deposition process; and
a microprocessor coupled to the V/I probe operable to receive the ion current and RF voltage measurements, compute a sputter rate from the ion current and RF voltage measurements, and detecting an abnormal condition during the deposition process in response to one of the sputter rate, ion current measurement, and RF voltage measurement deviating from expected values.

18. The system of claim 17, further comprising:
an RF power supply coupled to each RF-powered coils;
an RF matching network coupled to each RF power supply;
an RF power supply coupled to the V/I probe; and
an RF matching network coupled to the V/I probe.

19. The system of claim 17, wherein the microprocessor is operable to execute an algorithm operable to compute the sputter rate according to: Sputter Rate=B*I_{ION}*(V_{RF}−C), where I_{ION} is ion current and V_{RF} is RF voltage at the wafer.

20. The system of claim 17, wherein the microprocessor is operable to execute an algorithm operable to compute the sputter rate according to: Sputter Rate=B*I_{ION}*(V_{RF}−C), where I_{ION} is ion current and V_{RF} is RF voltage at the wafer, and further taking corrective actions in response to one of the sputter rate, ion current measurement, and RF voltage measurement deviating from expected values.
